(19) United States
(12) Patent Application Publication
(10) Pub. No.: US 2026/0348778 A1
(43) Pub. Date: Nov. 5, 2026

(54) STRAIN GAUGE

(71) Applicant: Texas Instruments Incorporated, Dallas, TX (US)

(72) Inventors: Vishnu RAVINUTHULA, Richardson, TX (US); Bradford HUNTER, Hutto, TX (US)

(73) Assignee: Texas Instruments Incorporated, Dallas, TX (US)

(21) Appl. No.: 19/194,168

(22) Filed: Apr. 30, 2025

(51) Int. Cl. G01L 1/22; G01R 19/257; G01R 31/364; G01R 31/3835; G01R 35/00

(52) U.S. Cl. CPC G01L 1/225; G01R 19/257; G01R 31/364; G01R 31/3835; G01R 35/005

(57) ABSTRACT

An apparatus includes a strain gauge and an analog-to-digital converter (ADC). The strain gauge includes a first resistor and a second resistor. The first resistor has a first terminal coupled to a power supply terminal and a second terminal. The second resistor has a first terminal coupled to the second terminal of the first resistor, and a second terminal coupled to a reference terminal. The ADC has a signal input coupled to the second terminal of the first resistor, and a reference input coupled to the power supply terminal.

### BACKGROUND

An integrated circuit may be subject to a variety of environmental effects that exert force on the integrated circuit. For example, mounting of a package containing the integrated circuit on a substrate may produce strain on the integrated circuit. Similarly, flexure of the substrate or temperature changes can change the strain applied to the integrated circuit. Components of the integrated circuit may be sensitive to strain such that performance of the integrated circuit varies with changes in the strain applied to the integrated circuit.

### SUMMARY

In one example, an apparatus includes a strain gauge and an analog-to-digital converter (ADC). The strain gauge includes a first resistor and a second resistor. The first resistor has a first terminal coupled to a power supply terminal and a second terminal. The second resistor has a first terminal coupled to the second terminal of the first resistor, and a second terminal coupled to a reference terminal. The ADC has a signal input coupled to the second terminal of the first resistor, and a reference input coupled to the power supply terminal.

In another example, An apparatus includes a strain gauge and an ADC. The strain gauge includes a first resistor, a second resistor, and a third resistor. The first resistor has a first terminal coupled to a power supply terminal, and a second terminal. The second resistor has a first terminal coupled to the power supply terminal, and a second terminal coupled to the second terminal of the first resistor. The third resistor has a first terminal coupled to the second terminal of the first resistor, and a second terminal coupled to a reference terminal, the third resistor is insensitive to strain. The ADC has a signal input coupled to the second terminal of the first resistor, and a reference input coupled to the power supply terminal.

In a further example, a system includes a battery and a battery monitor circuit. The battery has a first terminal and a second terminal. The battery monitor circuit has a first input coupled to the first terminal of the battery, and a second input coupled to the second terminal of the battery. The battery monitor circuit includes a power supply terminal, an ADC, and a strain gauge. The ADC has a signal input coupled to the first terminal of the battery; and a reference input coupled to the power supply terminal. The strain gauge includes a first resistor and a second resistor. The first resistor has a first terminal coupled to the power supply terminal and a second terminal coupled to the signal input of the ADC. The second resistor has a first terminal coupled to the second terminal of the first resistor, and a second terminal coupled to a reference terminal. The second resistor is orthogonal to the first resistor on an integrated circuit.

### BRIEF DESCRIPTION OF THE DRAWINGS

FIG. 1 is a block diagram of an example system that includes a battery monitor circuit that can adjust battery voltage measurements for strain.

FIG. 2 is a block diagram of an example analog-to-digital converter (ADC) circuit that includes calibration for strain, and is suitable for use in the system of FIG. 1.

FIG. 3A is a schematic diagram of an example strain gauge suitable for use in the ADC circuit of FIG. 2.

FIG. 3B is an example of layout of the resistors of the strain gauge of FIG. 3A on an integrated circuit.

FIG. 4 is a schematic diagram of another example strain gauge suitable for use in the ADC circuit of FIG. 2.

### DETAILED DESCRIPTION

Because integrated circuits are subject to strain related performance variation, some integrated circuits include circuitry that measures strain. The strain measurements may be applied to compensate for changes in performance caused by the strain. Strain can be measured by quantifying a change in a component (e.g., a resistor referred to as a strain resistor) of the integrated circuit that is sensitive to changes in strain. The resistance of the strain resistor may be quantified using an analog-to-digital converter (ADC) to measure the voltage drop across the strain resistor. However, the reference voltage used by the ADC to digitize the strain resistor's voltage drop, and the reference current flowing through the strain resistor to produce the voltage drop are subject to inaccuracies that can distort the resistance measurement. The strain gauge circuits described herein can measure the resistance of a strain resistor without sensitivity to the ADC reference voltage or the reference current flowing through the strain resistor. Accordingly, the strain gauge circuits can improve the accuracy of strain measurement and strain compensation in a variety of applications. The strain gauge circuits disclosed herein can also be used to measure stress or pressure in a variety of applications.

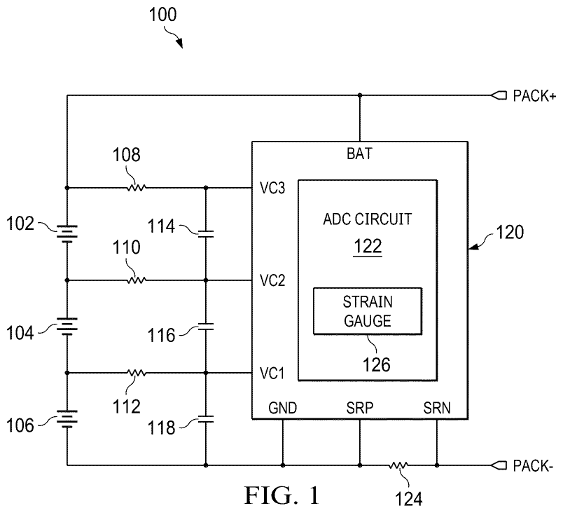

FIG. 1 is a block diagram of a system 100. The system 100 includes batteries 102, 104, and 106, resistors 108, 110, 112, and 124, capacitors 114, 116, and 118, and a battery monitor circuit 120. The battery monitor circuit 120 determines the charge present in each of the batteries 102, 104, and 106. The battery monitor circuit 120 may be provided as an integrated circuit. The battery monitor circuit 120 may also be referred to as a battery fuel gauge. The system 100 as shown in FIG. 1 includes three batteries. Alternatively, examples of the system 100 may include any number of batteries monitored by the battery monitor circuit 120.

The voltage across the batteries 102, 104, and 106 is provided at terminals PACK+ and PACK− for use by other circuits and/or systems (not shown). Each of the batteries 102, 104, and 106 has a first terminal (e.g., a positive terminal) and a second terminal (e.g., a negative terminal) coupled to the battery monitor circuit 120. The battery monitor circuit 120 has a battery terminal (BAT) coupled to the first terminal of the battery 102, and a ground terminal (GND) coupled to the second terminal of the battery 106. The battery monitor circuit 120 has a first input terminal (VC3) coupled to first terminal of the battery 102 via the resistor 108. The battery monitor circuit 120 has a second input terminal (VC2) coupled to the second terminal of the battery 102 and the first terminal of the battery 104 via the resistor 110. The battery monitor circuit 120 has a third input (VC1) coupled to the second terminal of the battery 104 and the first terminal of the battery 106 via the resistor 112. The capacitor 114 is coupled between the first input of the battery monitor circuit 120 and the second input of the battery monitor circuit 120. The capacitor 116 is coupled between the second input of the battery monitor circuit 120 and the third input of the battery monitor circuit 120. The capacitor 118 is coupled between the third input of the battery monitor circuit 120 and the ground terminal of the battery monitor circuit 120. The battery monitor circuit 120 has a first sense input (SRP) coupled to the second terminal of the battery 106, and a second sense input (SRN) coupled to the first sense input of the battery monitor circuit 120 via the resistor 124.

The battery monitor circuit 120 includes an analog-to-digital converter (ADC) circuit 122. The ADC circuit 122 digitizes the voltage across each of the batteries 102, 104, and 106 to measure the voltages, and digitizes the voltage across the resistor 124 to measure battery current. The charge determinations provided by the battery monitor circuit 120 are based on the ADC battery voltage measurements. Accuracy of the battery voltage and current measurements affects the charge measurements. Strain affects the accuracy of the voltage and current measurements provided by the ADC circuit 122. For example, a reference voltage used by the ADC circuit 122 may vary with strain. The ADC circuit 122 includes a strain gauge 126 that measures the strain present in the integrated circuit on which the battery monitor circuit 120 is provided. The ADC circuit 122 uses the strain measurements to calibrate the ADC battery voltage measurements and improve the accuracy thereof. In examples of the ADC circuit 122, the strain measurements are insensitive to reference voltage and reference current variation as described herein. Accordingly, the accuracy of the strain measurements is improved, and the accuracy of the calibrated battery voltage measurements is improved.

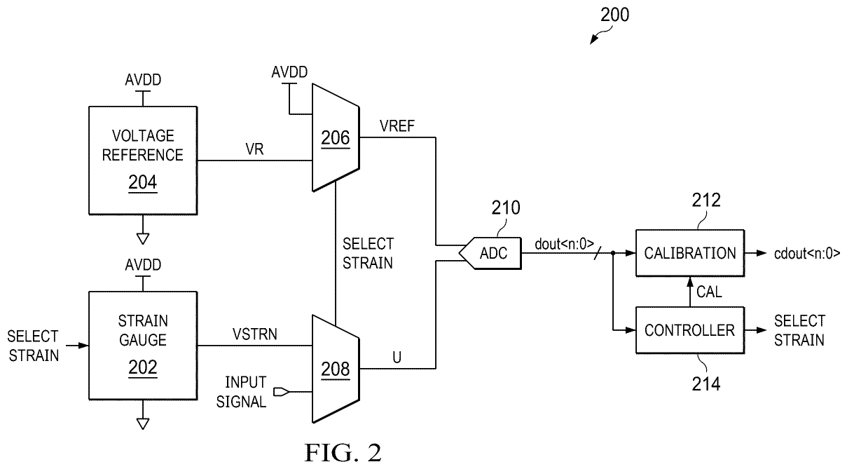

FIG. 2 is a block diagram of an ADC circuit 200 that includes calibration for strain. The ADC circuit 200 is an example of the ADC circuit 122. The ADC circuit 200 includes a strain gauge 202, a voltage reference circuit 204, multiplexers 206 and 208, an ADC 210, a calibration circuit 212, and a controller 214. The strain gauge 202 is an example of the strain gauge 126. The strain gauge 202, the voltage reference circuit 204, the multiplexers 206 and 208, the ADC 210, the calibration circuit 212, and the controller 214 may be provided on a same integrated circuit in some examples. The strain gauge 202 has a voltage input terminal, a reference terminal, an input, and an output. The voltage input terminal is coupled to a power supply terminal (AVDD). The reference terminal is coupled to a ground terminal, at electrical ground, in some examples.

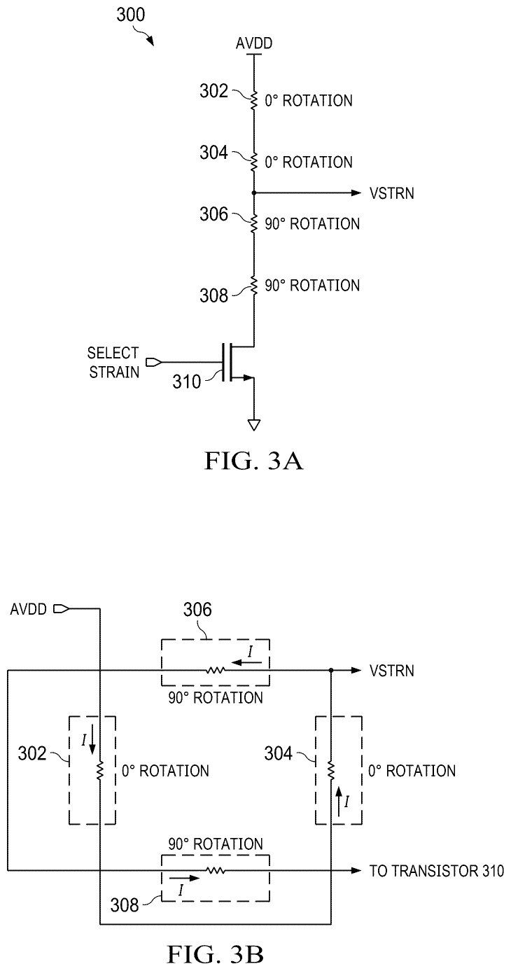

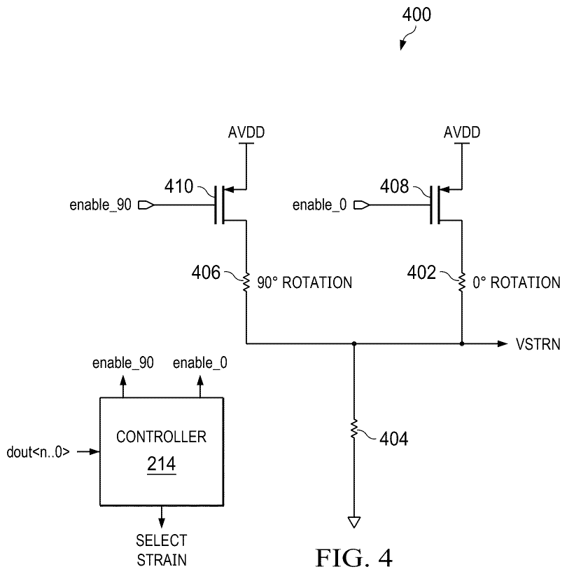

The strain gauge 202 includes one or more devices that are sensitive to strain. In some examples of the strain gauge 202, the strain sensitive devices are resistors coupled in series (as a voltage divider) between the voltage input terminal and the reference terminal. In some examples, at least some of the resistors are oriented orthogonally with respect to one another to sense strain in different directions. The resistors are coupled to the output of the strain gauge 202. A strain measurement signal (VSTRN), in this case a voltage, produced by the resistors is representative of strain on the integrated circuit. The strain gauge 202 provides VSTRN at the output of the strain gauge 202. Example circuitry of the strain gauge 202 is shown in FIGS. 3A, 3B, and 4. The input of the strain gauge 202 is coupled to the controller 214 for receipt of a control signal (STRAIN SELECT). STRAIN SELECT can enable and disable the strain gauge 202. For example, if strain select has a first logic state, then the strain gauge may provide VSTRN that represents strain sensed by the strain gauge 202. If STRAIN SELECT has a second logic state, then the strain gauge 202 may provide VSTRN that does not represent strain sensed by the strain gauge 202.

The voltage reference circuit 204 provides a reference voltage (VR) for use by the ADC 210. The voltage reference circuit 204 may include a bandgap circuit or other circuit that reduces the sensitivity of VR to temperature variation. However, the circuitry of the voltage reference circuit 204, and VR may be sensitive to strain. Accordingly, VR may vary with strain to the integrated circuit. Variation of VR reduces the accuracy of the output values generated by the ADC 210. The voltage reference circuit 204 has a voltage input terminal, a reference terminal, and an output. The voltage input terminal is coupled to AVDD. The reference terminal is coupled to the ground terminal. The voltage reference circuit 204 provides VR at the output of the voltage reference circuit 204.

The multiplexer 206 selects VR or the voltage at AVDD to provide to the ADC 210 as a reference voltage (VREF). The multiplexer 206 has a first input coupled to AVDD, a second input coupled to the output of the voltage reference circuit 204 for receipt of VR, a third input coupled to the controller 214 for receipt of STRAIN SELECT, and an output coupled to the ADC 210. The multiplexer 206 provides VREF at the output of the multiplexer 206. If STRAIN SELECT has a state that enables the strain gauge 202, then the multiplexer 206 provides the voltage at AVDD as VREF. Otherwise, the multiplexer 206 provides VR as VREF.

The multiplexer 208 selects a signal (INPUT SIGNAL) or VSTRN to provide to the ADC 210 as a signal (U) to be digitized. In some examples of the ADC circuit 200, INPUT SIGNAL may be the output of a multiplexer (not shown) that selects from multiple voltages (e.g., multiple battery voltages, voltage representing battery current, voltage representing temperature, etc.). The multiplexer 208 has a first input coupled to the output of the strain gauge 202, a second input coupled to a circuit that generates INPUT SIGNAL (not shown), a third input coupled to the controller 214 for receipt of STRAIN SELECT, and an output coupled to the ADC 210. The multiplexer 208 provides U at the output of the multiplexer 208. If STRAIN SELECT has a state that enables the strain gauge 202, then the multiplexer 208 provides VSTRN as U. Otherwise, the multiplexer 208 provides INPUT SIGNAL as U.

The ADC 210 has an output at which the ADC 210 provides a digital value dout <n:0> (e.g., a multibit digital output value) representing U. The ADC 210 generates the digital output value using comparisons to VREF. Error in VREF caused by strain produces error in dout <n:0>. The ADC 210 uses VREF received from the multiplexer 206 to digitize U provided by the multiplexer 208. The ADC 210 may be a delta-sigma ADC, a successive approximation ADC, or any other type of ADC. The ADC 210 has a reference input coupled to the output of the multiplexer 206 for receipt of VREF. The ADC 210 has a signal input coupled to the multiplexer 208 for receipt of U. The ADC 210 has an output, at which dout<n:0> is provided. The digital value dout <n:0> may include any number of bits in examples of the ADC 210.

The controller 214 receives dout<n:0> from the ADC 210, where dout<n:0> represents VSTRN, and processes dout<n:0> to determine an effect of strain on dout<n:0>. For example, the controller 214 may determine how the reference voltage (VREF) provided by the voltage reference circuit 204 varies with strain based on VSTRN represented by dout<n:0>. The controller 214 may compute a compensation value that can be used to calibrate dout<n:0> for strain. The controller 214 may be a processor, such as a microcontroller. The controller 214 has an input coupled to the output of the ADC 210 for receipt of dout<n:0>. The controller 214 has a first output, at which SELECT STRAIN is provided. The first output of the controller 214 is coupled to the input of the strain gauge 202, the third input of the multiplexer 206, and the third input of the multiplexer 208. The controller 214 has a second output, at which the strain compensation value (CAL) is provided, coupled to the calibration circuit 212.

The calibration circuit 212 applies the strain compensation value received from the controller 214 to calibrate (adjust) dout<n:0> for strain. For example, the calibration circuit 212 may multiply dout<n:0> by the strain compensation value received from the controller 214 to produce calibrated dout<n:0> (cdout<n:0>). The calibration circuit 212 has a first input coupled to the output of the ADC 210 for receipt of dout<n:0>. The calibration circuit 212 has a second input coupled to the output of the controller 214 for receipt of the strain calibration value. The calibration circuit 212 has an output at which cdout<n:0> is provided.

In operation, the controller 214 controls the strain gauge 202, the multiplexer 206, and the multiplexer 208 to measure strain. To measure strain, the controller 214 sets SELECT STRAIN to enable the strain gauge 202 to provide VSTRN representing the strain sensed by the strain gauge 202. SELECT STRAIN having this state may also set the multiplexer 208 to pass VSTRN to the ADC 210 as U, and set the multiplexer 206 to pass the voltage at AVDD to the ADC 210 as VREF. The ADC 210 digitizes VSTRN using the voltage at AVDD as the reference to provide a value of dout<n:0> representing VSTRN. Accordingly, VSTRN is:

$$V STRN = \frac{dout}{{2}^{n}} {V}_{AVDD} \qquad ( 1 )$$

where:
dout is the value of dout<n:0>;
n is the number of bits in dout<n:0>; and
V_{AVDD} is voltage at AVDD.

The controller 214 computes the value of a resistor of the strain gauge 202 to determine how the resistance of the resistance of the resistor has changed from its nominal value due to strain. The resistance may be computed as:

$${R}_{90} = \frac{{R}_{0} \frac{V STRN}{{V}_{AVDD}}}{1 - \frac{V STRN}{{V}_{AVDD}}} = \frac{{R}_{0} \frac{dout}{{2}^{n}}}{1 - \frac{dout}{{2}^{n}}} \qquad ( 2 )$$

where:
R₀ is the resistance of a first of two orthogonal resistors of the strain gauge 202; and
R₉₀ is the resistance of a second of two orthogonal resistors of the strain gauge 202. Equation (2) shows that because AVDD is used as the ADC reference voltage, the computation of resistance by the controller 214 is insensitive to the reference voltage of the ADC 210.

FIG. 3A is a schematic diagram of an example strain gauge 300. The strain gauge 300 is an example of the strain gauge 202. The strain gauge 300 includes resistors 302, 304, 306, and 308, and a transistor 310. The resistor 302 has a first terminal coupled to the voltage terminal (AVDD). The resistor 304 has a first terminal coupled to a second terminal of the resistor 302. The resistor 306 has a first terminal coupled to a second terminal of the resistor 304. The resistor 308 has a first terminal coupled to a second terminal of the resistor 306. VSTRN is provided at the first terminal of the resistor 306.

The transistor 310 enables current flow through the resistors 302, 304, 306, and 308 for strain measurement. The transistor 310 is turned on if strain measurement is being performed, and turn off if strain measurement is not being performed. The transistor 310 may be an n-channel metal oxide field effect transistor (NFET). The transistor 310 has a first terminal (e.g., drain) coupled to a second terminal of the resistor 308. The transistor 310 has a second terminal (e.g., source) coupled to a reference terminal (e.g., ground). The transistor 310 has a control terminal (e.g., gate) coupled to an output of the controller 214 for receipt of SELECT STRAIN. For example, if SELECT STRAIN is logic high, then the transistor 310 is turned on to enable current flow through the resistors 302, 304, 306, and 308, and strain measurement.

The transistor 310 may be omitted from some examples of the strain gauge 300. In such examples, the second terminal of the resistor 308 may be coupled to the reference terminal. In other examples of the strain gauge 300, the transistor 310 may be a p-channel metal oxide field effect transistor (PFET) coupled between AVDD and the first terminal of the resistor 302.

The resistors 302, 304, 306, and 308 may be provided on an integrated circuit, fabricated using a same process, and have a same temperature coefficient. The resistor 302 and the resistor 304 may be physically parallel to one another on the integrated circuit. The resistor 306 and the resistor 308 may be physically parallel to one another, and orthogonal to the resistor 302 and the resistor 304 on the integrated circuit. In some examples, the resistor 302 and the resistor 304 may be combined into a first resistor, and the resistor 306 and the resistor 308 may be combined into a second resistor. Because all of the resistors of the strain gauge 300 are coupled in series, multiple current sources are not used. Accordingly, the strain gauge 300 prevents error caused by provision of different currents (e.g., from different current sources) to different resistors.

FIG. 3B is an example of layout of the resistors 302, 304, 306, and 308 on an integrated circuit. In FIG. 3B the resistors 302, 304, 306, and 308 are arranged as a square (or rectangle) with the resistors 302 and 304 arranged as the sides of the square (or rectangle), and the resistors 306 and 308 arranged as the top and bottom of the square (or rectangle). The resistors 302 and 304 are physically parallel to one another, and the resistors 306 and 308 are physically parallel to one another and orthogonal to the resistors 302 and 304.

In some examples of the strain gauge 300, all of the resistors 302, 304, 306, and 308 are sensitive to strain. Because the resistors 302 and 304 are orthogonal to the resistors 306 and 308, the resistors 302 and 304 may be sensitive to strain in a first direction, and the resistors 306 and 308 may be sensitive to strain in a second direction that is orthogonal to the first direction. In some examples of the strain gauge 300, the resistors 302 and 304 are sensitive to strain, and the resistors 306 and 308 are insensitive to strain. In some examples of the strain gauge 300, the resistors 302 and 304 are insensitive to strain, and the resistors 306 and 308 are sensitive to strain.

FIG. 4 is a schematic diagram of an example strain gauge 400. The strain gauge 400 is an example of the strain gauge 202. The strain gauge 400 includes resistors 402, 404, and 406, and transistors 408 and 410. The transistors 408 and 410 may be PFETs. The resistors 402 and 406, and the transistors 408 and 410 may be provided on an integrated circuit. The resistor 406 may be orthogonal to the resistor 402 on the integrated circuit. The resistors 402 and 406 may be fabricated using a same process, and may have a same temperature coefficient. The resistor 404 may be insensitive to strain. The resistor 404 may be external to the integrated circuit, or may be provided on the integrated circuit with the resistors 402 and 406. The transistor 408 may be turned on to measure strain using the resistor 402. The transistor 410 may be turned on to measure strain using the resistor 406.

The transistor 408 has a first terminal (e.g., source) coupled to AVDD. The transistor 408 has a second terminal (e.g., drain) coupled to a first terminal of the resistor 402. The resistor 402 has a second terminal coupled to a first terminal of the resistor 404. A control terminal (e.g., gate) of the transistor 408 is coupled to an output of the controller 214 for receipt of the control signal enable_0. A second terminal of the resistor 404 is coupled to a reference terminal (e.g., ground).

The transistor 410 has a first terminal (e.g., source) coupled to AVDD. The transistor 410 has a second terminal (e.g., drain) coupled to a first terminal of the resistor 406. The resistor 406 has a second terminal coupled to the second terminal of the resistor 402 and the first terminal of the resistor 404. A control terminal (e.g., gate) of the transistor 410 is coupled to an output of the controller 214 for receipt of the control signal enable_90.

The controller 214 may set enable_0 to a logic low state to use the resistor 402 for strain measurement, and may set enable_90 to a logic low state to use the resistor 406 for strain measurement. Accordingly, using the strain gauge 400, effects of strain on the resistor 402 and the resistor 406 can be measured independently. Because the resistor 404 is insensitive to strain, the change in resistance of the resistors 402 and 406 due to strain can be accurately measured.

In another example of the strain gauge 400, the second terminal of the resistor 404 is coupled to AVDD, and the transistors 408 and 410 are NFETs with the first terminal of the transistor 408 and the first terminal of the transistor 410 coupled to the reference terminal.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET)) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a strain gauge including:
a first resistor having a first terminal coupled to a power supply terminal and a second terminal;
a second resistor having a first terminal coupled to the second terminal of the first resistor, and a second terminal coupled to a reference terminal; and
an analog-to-digital converter (ADC) having a signal input coupled to the second terminal of the first resistor, and a reference input coupled to the power supply terminal.

2. The apparatus of claim 1, wherein the first resistor is orthogonal to the second resistor on an integrated circuit.

3. The apparatus of claim 1, further comprising:
a third resistor having a first terminal coupled to the second terminal of the first resistor, and a second terminal coupled to the first terminal of the second resistor; and
a fourth resistor having a first terminal coupled to the second terminal of the second resistor, and a second terminal coupled to the reference terminal.

4. The apparatus of claim 3, wherein the third resistor is physically parallel to the first resistor, and orthogonal to the second resistor, and the fourth resistor is physically parallel to the second resistor.

5. The apparatus of claim 1, further comprising:
a first multiplexer having a first signal input coupled to the power supply terminal, a second signal input, a control input, and an output coupled to the reference input of the ADC;
a voltage reference circuit having an output coupled to the second signal input of the first multiplexer; and
a second multiplexer having a first signal input coupled to the second terminal of the first resistor, a second signal input, a control input coupled to the control input of the first multiplexer, and an output coupled to the signal input of the ADC.

6. The apparatus of claim 5, further comprising a transistor having a first terminal coupled to the second terminal of the second resistor, a second terminal coupled to the reference terminal; and a control terminal.

7. The apparatus of claim 6, further comprising a controller having an output coupled to the control terminal of the transistor, the control input of the first multiplexer, and the control input of the second multiplexer, the controller capable of determining a resistance of the second resistor based on a resistance of the first resistor, a digital value representing a voltage at the first terminal of the second resistor, and a number of bits in the digital value.

8. An apparatus comprising:
a strain gauge including:
a first resistor having a first terminal coupled to a power supply terminal, and a second terminal;
a second resistor having a first terminal coupled to the power supply terminal, and a second terminal coupled to the second terminal of the first resistor;
a third resistor having a first terminal coupled to the second terminal of the first resistor, and a second terminal coupled to a reference terminal, the third resistor is insensitive to strain; and
an analog-to-digital converter having a signal input coupled to the second terminal of the first resistor, and a reference input coupled to the power supply terminal.

9. The apparatus of claim 8, wherein the first resistor is orthogonal to the second resistor on an integrated circuit.

10. The apparatus of claim 8, further comprising:
a first transistor having a first terminal coupled to the power supply terminal, a second terminal coupled to the first terminal of the first resistor, and a control terminal; and
a second transistor having a first terminal coupled to the power supply terminal, a second terminal coupled to the first terminal of the second resistor, and a control terminal.

11. The apparatus of claim 10, further comprising:
a first multiplexer having a first signal input coupled to the power supply terminal, a second signal input, a control input, and an output coupled to the reference input of the ADC;
a voltage reference circuit having an output coupled to the second signal input of the first multiplexer; and
a second multiplexer having a first signal input coupled to the second terminal of the first resistor, a second signal input, a control input coupled to the control input of the first multiplexer, and an output coupled to the signal input of the ADC.

12. The apparatus of claim 11, further comprising a controller having a first output coupled to the control terminal of the first transistor, a second output coupled to the control terminal of the second transistor, and a third output coupled to the control input of the first multiplexer and the control input of the second multiplexer, the controller capable of:
determining a resistance of the first resistor based on a resistance of the third resistor, a digital value representing a voltage at the first terminal of the third resistor, and a number of bits in the digital value; and
determining a resistance of the second resistor based on a resistance of the third resistor, a digital value representing a voltage at the first terminal of the third resistor, and a number of bits in the digital value.

13. The apparatus of claim 12, wherein the controller is capable of determining a strain compensation value based on the resistance of the first resistor or the resistance of the second resistor.

14. The apparatus of claim 13, further comprising a calibration circuit coupled to the output of the ADC, the calibration circuit capable of applying the strain compensation value to adjust digital values generated by the ADC.

15. A system comprising:
a battery having a first terminal and a second terminal;
a battery monitor circuit having a first input coupled to the first terminal of the battery, and a second input coupled to the second terminal of the battery, the battery monitor circuit including:
a power supply terminal;
an analog-to-digital converter (ADC) having a signal input coupled to the first terminal of the battery; and a reference input coupled to the power supply terminal; and
a strain gauge including:
a first resistor having a first terminal coupled to the power supply terminal and a second terminal coupled to the signal input of the ADC; and
a second resistor having a first terminal coupled to the second terminal of the first resistor, and a second terminal coupled to a reference terminal, wherein the second resistor is orthogonal to the first resistor on an integrated circuit.

16. The system of claim 15, further comprising:
a third resistor having a first terminal coupled to the second terminal of the first resistor, and a second terminal coupled to the first terminal of the second resistor; and
a fourth resistor having a first terminal coupled to the second terminal of the second resistor, and a second terminal coupled to the reference terminal.

17. The system of claim 16, wherein the third resistor is physically parallel to the first resistor, and orthogonal to the second resistor, and the fourth resistor is physically parallel to the second resistor and orthogonal to the first resistor.

18. The system of claim 15, further comprising:
a transistor having a first terminal coupled to the second terminal of the second resistor, a second terminal coupled to the reference terminal; and a control terminal;
a first multiplexer having a first signal input coupled to the power supply terminal, a second signal input, a control input coupled to the control terminal of the transistor, and an output coupled to the reference input of the ADC;
a voltage reference circuit having an output coupled to the second signal input of the first multiplexer; and
a second multiplexer having a first signal input coupled to the second terminal of the first resistor, a second signal input, a control input coupled to the control input of the first multiplexer, and an output coupled to the signal input of the ADC.

19. The system of claim 18, further comprising a controller having an output coupled to the control terminal of the transistor, the control input of the first multiplexer, and the control input of the second multiplexer, the controller capable of:
determining a resistance of the second resistor based on:
a resistance of the first resistor,
a digital value representing a voltage at the first terminal of the second resistor, and
a number of bits in the digital value; and
determining a strain compensation value based on the resistance of the second resistor.

20. The system of claim 19, further comprising a calibration circuit coupled to the output of the ADC, the calibration circuit capable of applying the strain compensation value to adjust digital values generated by the ADC.
